(19) United States
(12) Patent Application Publication
(10) Pub. No.: US 2006/0040511 A1
(43) Pub. Date: Feb. 23, 2006

(54) [METHOD OF FABRICATING SHALLOW TRENCH ISOLATION STRUCTURE FOR REDUCING WAFER SCRATCH]

(76) Inventor: Jason Lu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/711,003

(22) Filed: Aug. 17, 2004

(51) Int. Cl. H01L 21/76; H01L 21/31; H01L 21/469

(52) U.S. Cl. 438/792

(57) ABSTRACT

A method of fabricating a shallow trench isolation structure for reducing wafer scratch reducing scratch on a wafer surface is provided. A parameter of a processing operation is controlled in a manner to reduce an amassment of material over the wafer surface. Thus, a step height from the surface of the substrate, which would otherwise cause micro-scratches on the wafer surface in a subsequent chemical-mechanical polishing operation, can be effectively reduced.

### BACKGROUND OF INVENTION

1. Field of the Invention

The present invention relates to a process method of fabricating semiconductor device and for reducing wafer scratch. More particularly, the present invention relates to a method of fabricating shallow trench isolation structure for reducing wafer scratch.

2. Description of Related Art

Due to the rapid development of integrated circuit technologies, devices miniaturization and integration are the major trends in the semiconductor manufacturing industry. As the dimension of device continues to shrink and the level of integration continues increases, structures for isolating device have to reduce correspondingly. Hence, with device miniaturization, isolating structures are increasingly difficult to fabricate. Because shallow trench isolation (STI) is scalable without causing any bird's beak encroachment problem as in the conventional local oxidation of silicon (LOCOS) process, it is the preferred isolation technique for sub-micron metal-oxide-semiconductor fabrication process.

In the conventional process of fabricating a shallow trench isolation, a patterned mask layer is formed on a substrate. Thereafter, the substrate is etched using the patterned mask layer as an etching mask to form a trench in the substrate. Next, insulation material is deposited to fill the trench and then a chemical-mechanical polishing process is performed to remove the insulation material outside the trench. Finally, the patterned mask layer is removed.

However, before carrying out the steps of fabricating the shallow trench isolation, a laser mark is usually stamped on one corner of the chip's front surface so that the laser mark can be read out by a reader in a subsequent process to identify the chip. Since the laser mark is etched on the chip using a laser beam, the region illuminated by the laser beam will form a structure with a pit 102 in the middle and a protrusion 104 on each side of the pit 102 as shown in FIG. 1. However, the presence of these protrusions 104 affects the subsequent process of fabricating shallow trench isolation.

If the protrusion 104 and the surface of the substrate 100 has a large step height H1, the process of removing the insulation material outside the trench in a chemical-mechanical polishing will often lead to the formation of micro-scratches 200 as shown in FIG. 2(a) and FIG. 2(b). FIG. 2(a) is a picture of a wafer captured by a scanning electron microscope after forming the shallow trench isolation structures. FIG. 2(b) is a picture of the scratches on a wafer captured by a scanning electron microscope after forming the shallow trench isolation structures. The aforementioned micro-scratches are formed on the wafer because the chemical-mechanical polishing process for removing the insulation material outside the trench also attempts to remove the protrusions made from a harder material such as silicon. Thus, as the polishing head moves around in cycles, the surface of the substrate is repeatedly scratched. When micro-scratches are plentiful on the wafer surface, the capacity of the shallow trench isolation structures to isolate devices may be affected.

### SUMMARY OF INVENTION

Accordingly, the present invention is directed to a method of fabricating a shallow trench isolation structure for method of reducing wafer scratch in which the heights of the protrusions on the surface of a wafer is reduced for reducing the formation of micro-scratches on the surface in a subsequent chemical-mechanical polishing process.

The present invention is directed to a method of fabricating a shallow trench isolation structure for reducing wafer scratch capable of reducing step heights of any protruding material on the surface of a wafer and thereby reducing formation of micro scratches on the surface of the wafer in a subsequent planarization process.

According to an embodiment of the present invention, a method of fabricating a shallow trench isolation structure for reducing wafer scratch of reducing wafer scratch is provided. First, a substrate is provided. The present inventors observed that protrusion on the substrate resulting from an amassment of material in a former processing operation leads to formation of a large amount of micro-scratches on the wafer surface in a CMP process if the step height of the protrusion is not reduced prior to performing the CMP process. To reduce the formation of micro-scratch on the wafer surface, a parameter of a processing operation prior to a CMP process is adjusted so as to reduce the step height of the protrusion on the wafer surface.

According to the present invention, the step height of protrusion on the substrate formed in a former processing operation is reduced so that the severity of scratching in a subsequent chemical-mechanical polishing operation is significantly attenuated.

The present invention also directed to a process of fabricating shallow trench isolation structure. First, a substrate is provided. A laser marking process is carried out to form a laser mark on the substrate, wherein a parameter of the laser marking process is controlled in a manner to reduce the step height of any protrusions formed over the surface of the substrate. It should be noted that if the parameter of the laser marking is not adjusted, the step height of the protrusion formed during the laser marking operation will be higher compared to that when the parameter of the laser marking operation is adjusted. Thereafter, a patterned mask layer is formed over the substrate. Using the patterned mask layer as an etching mask, the substrate is etched to form a trench. An insulation material is deposited over the substrate to fill the trench. A chemical-mechanical polishing operation is carried out to remove the insulation material formed outside the trench. Finally, the patterned mask layer is removed.

Because the step height of the protrusion on the substrate during the laser marking process is reduced by controlling the energy of the laser beam, the subsequent chemical-mechanical polishing operation in the shallow trench isolation fabrication process for removing excess insulation material will produce minimal scratching.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing part of the surface of a substrate after a conventional laser marking operation.

FIG. 2(a) is a picture of a wafer captured by a scanning electron microscope after forming the shallow trench isolation structures.

FIG. 2(b) is a picture of the scratches on a wafer captured by a scanning electron microscope after forming the shallow trench isolation structures.

FIG. 3 is a schematic cross-sectional view showing part of the surface of a substrate according to one embodiment of the present invention.

FIG. 4 is a flow diagram showing the steps for fabricating a shallow trench isolation according to one embodiment of the present invention.

FIGS. 5A through 5C are schematic cross-sectional views showing the process for fabricating a shallow trench isolation structure according to one embodiment of the present invention.

FIG. 6 is a schematic cross-sectional view showing part of the surface of a substrate after performing a laser marking process according to one embodiment of the present invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

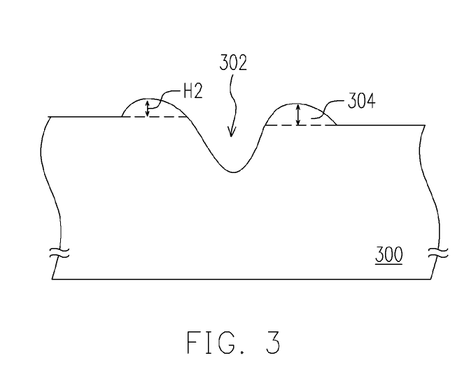

FIG. 3 is a schematic cross-sectional view showing part of the surface of a substrate according to one embodiment of the present invention. The method of reducing wafer scratch includes the following steps. First, a substrate 300 is provided. Thereafter, a pre-processing operation of the substrate 300 is carried out. The pre-processing operation is a laser marking operation or other suitable types of operations, for example. Although the pre-processing operation leads to an amassment of material on the substrate 300 to form expected or unexpected protrusions 304 or pits 302 in the substrate 300, an effective control of related processing parameters is able to reduce the maximum step height H2. Using a laser marking process as an example, the energy of a laser beam can be controlled to minimize the step height H2. The energy of the laser beam used is, for example, smaller than 1000 micro-joule (μ j) so that the step height H2 is smaller than 4 micrometer (μ m). Therefore, the extent of the formation of micro-scratches on the surface of the substrate 300 is minimized when a chemical-mechanical polishing operation is subsequently carried out.

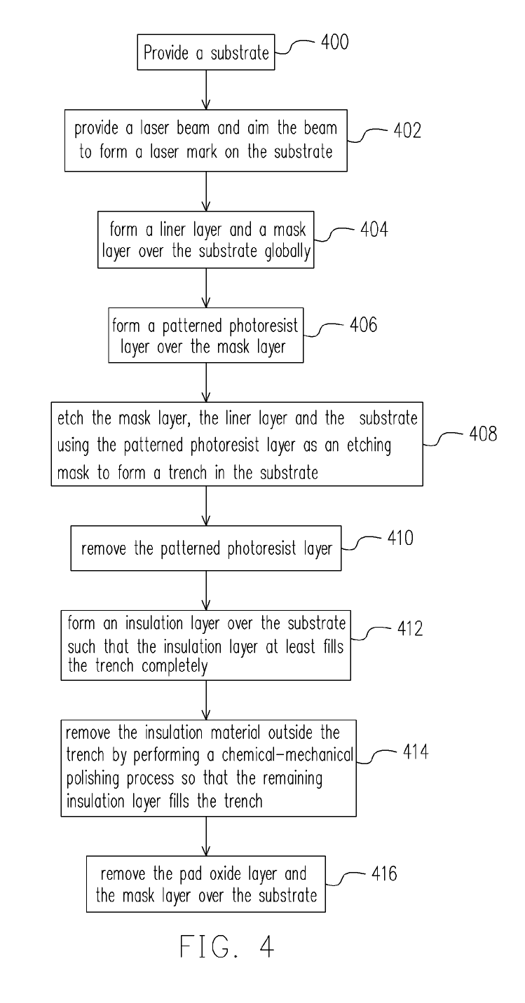

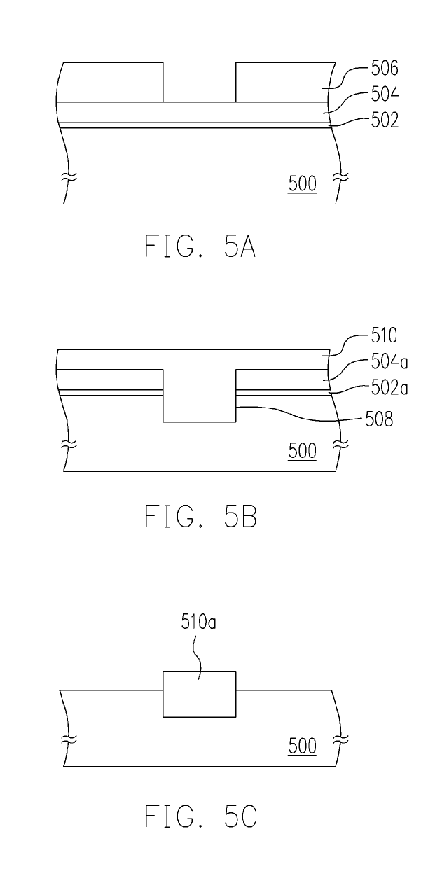

In the present embodiment, a laser marking process is performed prior to the process of fabricating a shallow trench isolation structure. However, this should by no means constrain the scope of the present invention. FIG. 4 is a flow diagram showing the steps for fabricating a shallow trench isolation structure according to one preferred embodiment of the present invention. FIGS. 5A through 5C are schematic cross-sectional views showing the process for fabricating a shallow trench isolation according to one embodiment of the present invention.

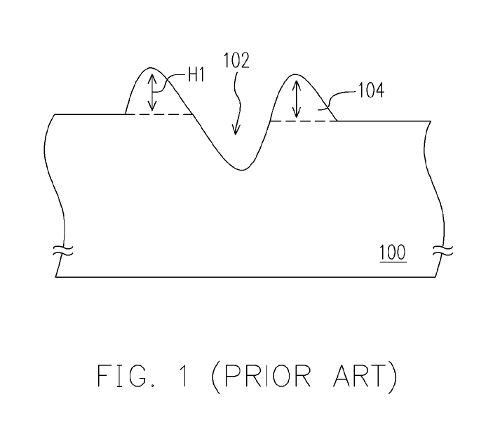

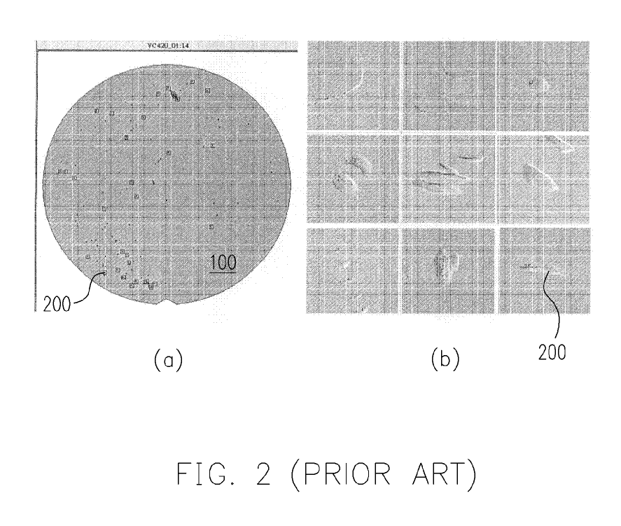

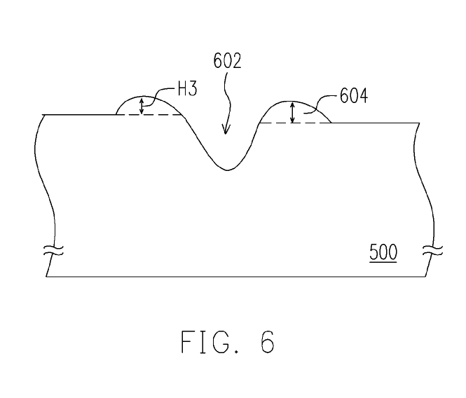

As shown in FIG. 4, a substrate is provided (step 400). Thereafter, a laser beam is used to form a laser mark on the surface of the substrate (step 402). In the process of forming the laser mark (step 402), energy of the laser beam is adjusted to minimize the step height of protrusion amassed on the substrate surface. In particular, a low energy laser beam can be deployed to reduce the step height between the protrusion and the substrate surface. Although pits 602 are formed in the illuminated region of the laser beam as shown in FIG. 6 using a low energy laser beam (step 402), the protrusion on each side of the pit 602 has a step height H3 smaller than the step height H1 in a conventional method (shown in FIG. 1). The energy used in the laser beam is, for example, smaller than 1000 micro-joule (μ j) Watts so that the step height H3 is smaller than 4 micrometer (μ m). Therefore, the extent of formation of the micro-scratches on the surface of the substrate 500 is minimized when other steps necessary for fabricating a shallow trench isolation structure is subsequently carried out.

As shown in FIGS. 4 and 5A, a liner layer 502 and a mask layer 504 are formed over the substrate 500 globally (step 404). The liner layer 502 can be a silicon oxide layer formed, for example, by performing a thermal oxidation process. The mask layer 504 is a silicon nitride layer formed, for example, by performing a chemical vapor deposition process. Thereafter, a patterned photoresist layer 506 is formed over the mask layer 504 (step 406) to expose the area for forming the shallow trench isolation structure.

As shown in FIGS. 4 and 5B, the mask layer 504, the liner layer 502 and the substrate 500 are sequentially etched using the patterned photoresist layer 506 as an etching mask to form a trench 508, a liner layer 502a and a mask layer 504a (step 408). Thereafter, the patterned photoresist layer 506 is removed (step 410). Next, an insulation layer 510 is formed over the substrate 500 (step 412). The insulation layer 510 at least fills the trench completely. The insulation layer 510 can be a silicon oxide layer formed, for example, by performing a high-density plasma chemical vapor deposition (HDP-CVD) process.

As shown in FIGS. 4 and 5C, a chemical-mechanical polishing (CMP) process is carried out to remove a layer of the insulation layer 510 outside the trench 508 so that an insulation layer 510a is formed within the trench 508 (step 414). It should be noted that the step height of the protrusion on the substrate 500 produced in the former laser marking process (step 402) is small. Thus, negligible amount of micro-scratches are formed on the substrate 500 after the chemical-mechanical polishing operation. Finally, the pad oxide layer 502a and the mask layer 504a on the substrate 500 are removed (step 416) to complete the formation of the shallow trench isolation structure.

In the present invention, the step height of the protrusion on the substrate during the laser marking process is reduced by controlling the energy of the laser beam. Hence, the subsequent chemical-mechanical polishing operation in the process of fabricating the shallow trench isolation structure for removing excess insulation material will produce minimal scratching.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of fabricating a shallow trench isolation structure for reducing wafer scratch reducing wafer scratch, comprising the steps of:
providing a substrate; and
performing a processing operation over a surface of the substrate prior to performing a chemical mechanical polishing process, wherein at least a protrusion is formed over the surface of the substrate during the processing operation, and wherein a parameter of the processing operation is adjusted in a manner to reducing a step height of the protrusion compared that without adjusting the parameter of the processing operation.

2. The method of reducing wafer scratch of claim 1, wherein the processing operation comprises a laser marking process.

3. The method of reducing wafer scratch of claim 2, wherein the step of adjusting a parameter of a processing operation comprises adjusting an energy of the laser beam used in the laser marking process.

4. The method of reducing wafer scratch of claim 3, wherein the energy of the laser beam used in the laser marking process is smaller than 1000 micro-joule (μ j).

5. The method of reducing wafer scratch of claim 3, wherein the step of adjusting parameter of the processing operation comprises reducing the step height to a level below 4 micrometer (μ m).

6. A method of fabricating a shallow trench isolation structure for reducing wafer scratch process of fabricating a shallow trench isolation structure, comprising the steps of:
providing a substrate;
performing a laser marking operation to form a laser mark on the substrate, wherein at least a protrusion is formed during the laser marking operation due to an amassment of material, and wherein a parameter of the laser marking operation is adjusted in a manner to reduce a step height of the protrusion compared to that without adjusting the parameter;
forming a patterned mask layer over the substrate;
etching the substrate using the patterned mask layer as an etching mask to form a trench;
forming an insulation layer over the substrate, wherein the insulation layer completely fills the trench;
removing a portion of the insulation layer by performing a chemical-mechanical polishing process; and
removing the patterned mask layer.

7. The method process of claim 6, wherein step of controlling the parameter of the laser marking operation includes adjusting an energy of the laser beam used in the laser marking operation to a level below 1000 micro-joule (μ j).

8. The method process of claim 6, wherein the step of controlling the parameter in the laser marking operation comprises reducing the step height to a level below 4 micrometer (μ m).
